(19) United States
(12) Patent Application Publication
(10) Pub. No.: US 2010/0079192 A1
(43) Pub. Date: Apr. 1, 2010

(54) Drive for a half-bridge circuit

(76) Inventor: Bernhard Strzalkowski, Munich (DE)

Correspondence Address: SLATER & MATSIL LLP, 17950 PRESTON ROAD, SUITE 1000, DALLAS, TX, 75252, US

(21) Appl. No.: 12/240,245

(22) Filed: Sep. 29, 2008

(51) Int. Cl. H03K 17/56

(52) U.S. Cl. 327/419

(57) ABSTRACT

A method for driving a half-bridge is described.

### BACKGROUND

Half-bridge circuits can be used to drive inductive loads such as electric motors, with each half-bridge circuit being connected between a terminal for a positive and a negative supply potential, and each having an output terminal for connecting the load. For driving a DC motor, two such half-bridge circuits are connected up into a bridge circuit, and for driving a 3-phase motor, three such half-bridge circuits are connected up into a bridge circuit. In such circuit arrangements, a current consumption of the load is controlled by pulse-width modulated driving of the half-bridge circuit, i.e. by pulse-width modulated driving of semiconductor switching elements that form the half-bridge circuits. Two semiconductor switching elements forming a half-bridge circuit can here be driven with respect to each other in a complementary fashion such that while one of the semiconductor switching elements is being driven in the OFF state, the other semiconductor switching element conducts, and vice versa. In order to avoid cross currents in the half-bridge circuit, dead times can be provided between switching off the one semiconductor switching element and switching on the other semiconductor switching element.

### SUMMARY

This description relates to a method for driving a half-bridge circuit comprising two semiconductor switching elements, each having a load path and a drive terminal, and two freewheeling elements, each of which is connected in parallel with the load path of one of the semiconductor switching elements, where the method comprises: preventing at least one of the two semiconductor switching elements from being driven in the ON state at least during a time interval when its freewheeling element is forward biased.

### SHORT DESCRIPTION

Examples are explained below with reference to figures. The figures are used to explain the basic principle, and only show those aspects needed to explain this basic principle. Unless stated otherwise, in the figures, the same references denote identical signals and circuit components having the same relevance.

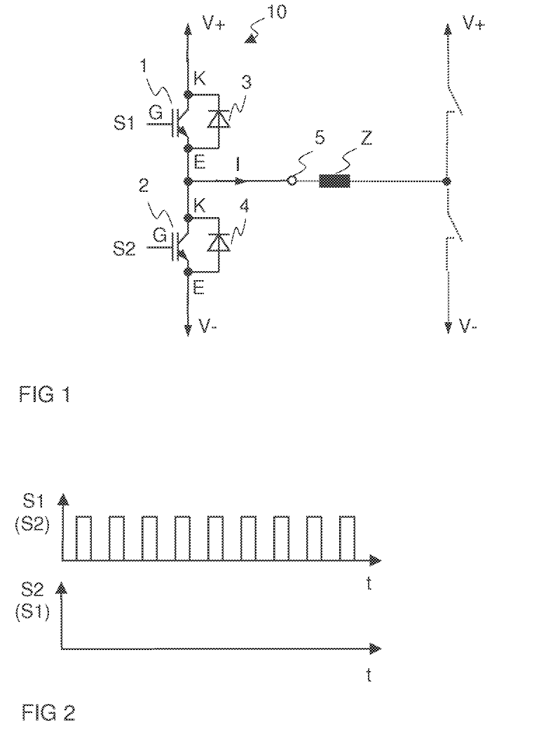

FIG. 1 shows an example of a half-bridge circuit having two semiconductor switching elements.

FIG. 2 shows an example of a method for driving the two semiconductor switching elements.

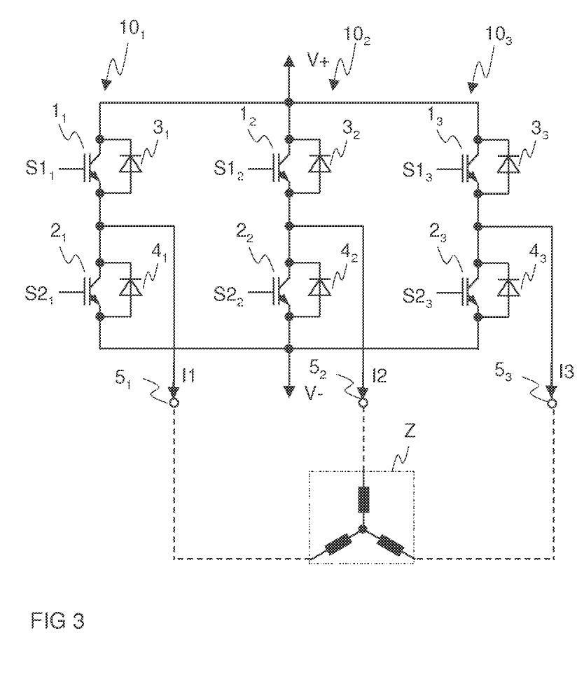

FIG. 3 shows an example of a 3-phase power converter having three half-bridge circuits.

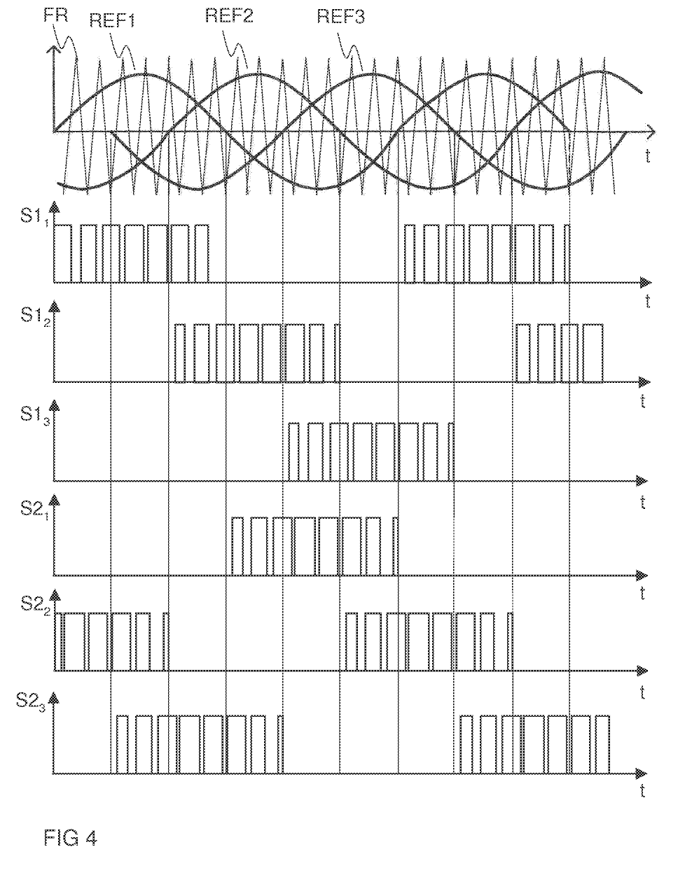

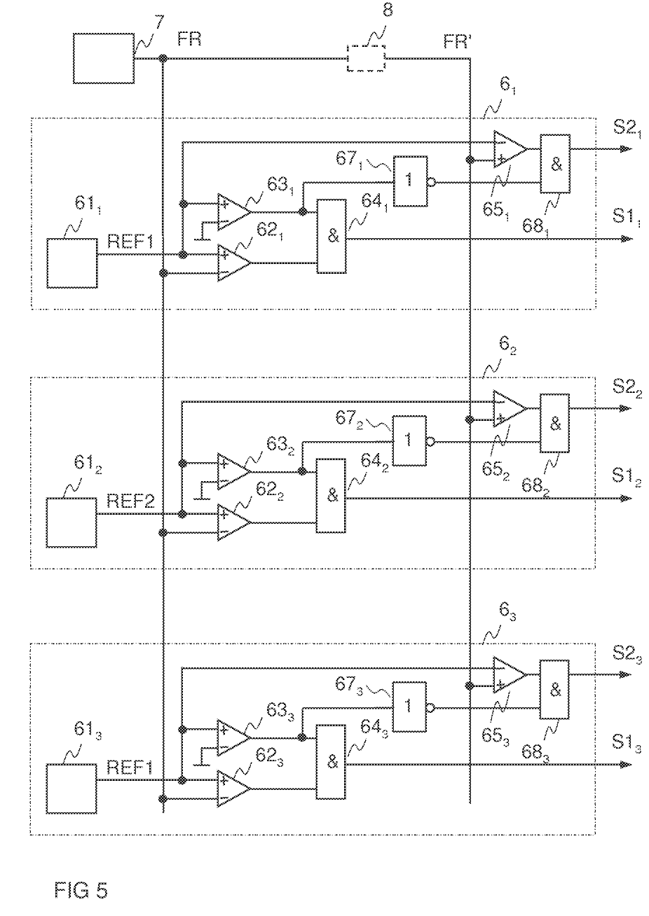

FIG. 4 uses signal time waveforms to show an example of a method for driving the half-bridge circuits of a 3-phase power converter.

FIG. 5 shows an example of a circuit arrangement for generating the drive signals shown in FIG. 4.

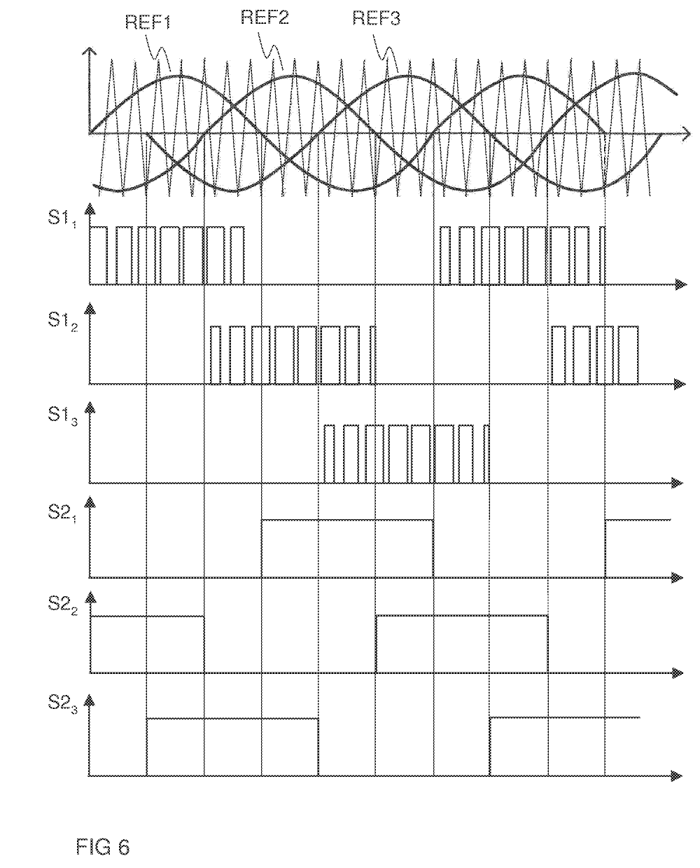

FIG. 6 uses signal time waveforms to show another example of a method for driving the half-bridge circuits of a 3-phase power converter.

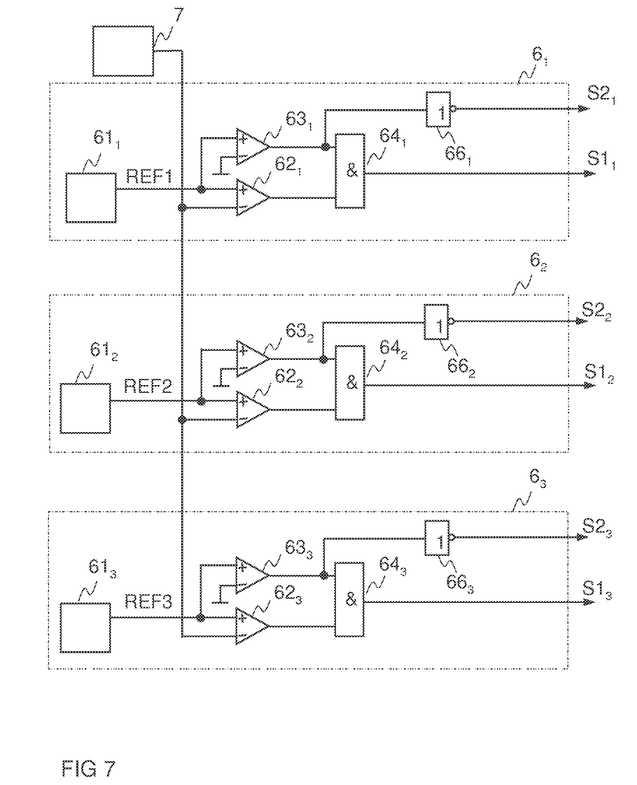

FIG. 7 shows an example of a circuit arrangement for generating the drive signals shown in FIG. 6.

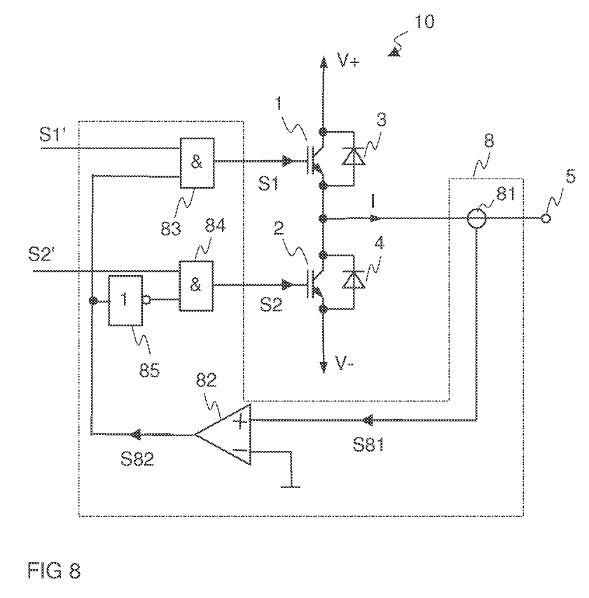

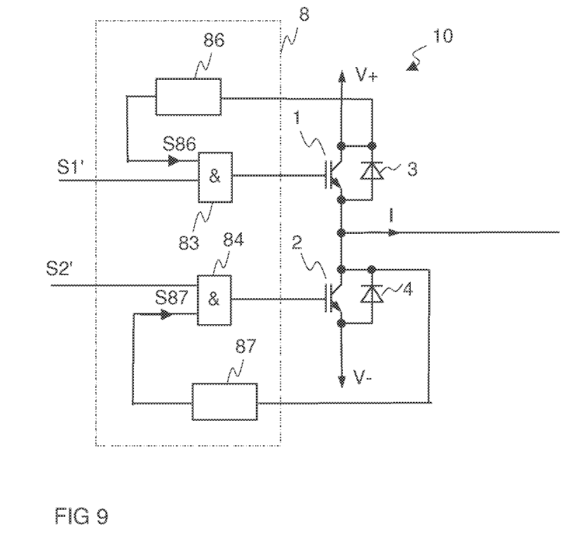

FIG. 8 shows another example of a drive circuit for generating the drive signals for semiconductor switching elements of a half-bridge circuit.

FIG. 9 shows another example of a drive circuit for generating the drive signals for semiconductor switching elements of a half-bridge circuit.

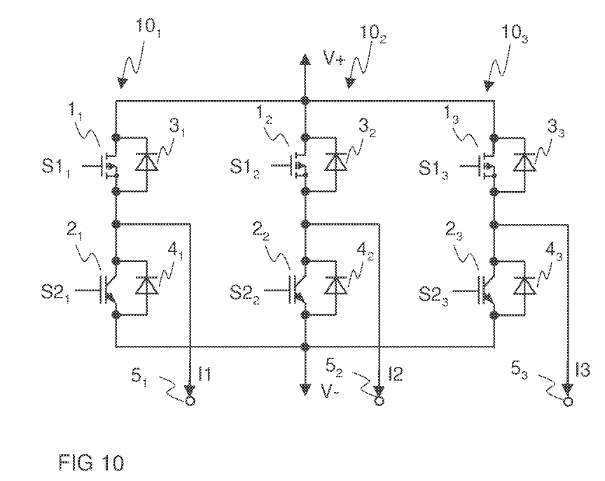

FIG. 10 shows another example of a 3-phase power converter.

### DETAILED DESCRIPTION

FIG. 1 uses an electrical equivalent circuit to show an example of a half-bridge circuit or half-bridge 10. This half-bridge comprises two semiconductor switching elements 1, 2, each having a drive terminal and a load path running between a first and a second load-path terminal. The load paths of the two semiconductor switching elements 1, 2 are connected in series with each other between terminals for a first and a second supply potential V+, V−, which are also referred to below as the positive and negative supply potential. An output 5 of the half-bridge 10 is formed by a circuit node lying between the load paths of the two semiconductor switching elements 1, 2. The semiconductor switching element 1 lying closer to the terminal for the positive supply potential V+ is also referred to below as the high-side switch, while the second semiconductor switching element 2 arranged closer to the negative supply potential V− is also referred to below as the low-side switch.

The semiconductor switching elements 1, 2 are implemented as an IGBT in the example shown (Insulated Gate Bipolar Transistor). These IGBTs each have a gate terminal G as the drive terminal, a collector terminal K as the first load-path terminal, an emitter terminal E as the second load-path terminal and load paths running between the collector and emitter terminals K, E. The two IGBTs can be of the same type, and are n-channel IGBTs in the example shown. The two IGBTs are here connected up so that their respective collector terminal lies closer to the positive supply potential V+ in the circuit formed between the positive and the negative supply potential V+, V−. It should be pointed out in this context that the use of IGBTs as semiconductor switching elements is merely to be considered as an example. Obviously there is also the option to implement the half-bridge 10 using other semiconductor switching elements, in particular MOSFETs (Metal Oxide Semiconductor Field Effect Transistor). MOSFETs have a gate terminal as the drive terminal and drain and source terminals as the load-path terminals.

Moreover, the two semiconductor switching elements 1, 2 need be neither of the same component type nor of the same channel type. For example, one of the two semiconductor switching elements can be implemented as an IGBT and the other of the two semiconductor switching elements as a MOSFET. If the semiconductor switching elements are of the same component type, i.e. either IGBTs or MOSFETs, for example, then different channel types can be provided for the two semiconductor switching elements, i.e. one of the two semiconductor switching elements can be a component having an n-channel, for example, while the other is a component having a p-channel.

A freewheeling element is connected in parallel with each of the load paths of the semiconductor switching elements 1, 2, namely a first freewheeling element 3 in parallel with the load path of the first semiconductor switching element 1 and a second freewheeling element 4 in parallel with the load path of the second semiconductor switching element 2. The two freewheeling elements 3, 4 are rectifier elements such as diodes, which are connected in the same polarity direction and in such a way that they do not conduct when a supply voltage lies between the supply potential terminals, i.e. when a positive supply potential V+ lies at the first supply potential terminal and a negative supply potential V− at the second supply potential terminal, and when the output 5 of the half-bridge circuit 10 is open.

The half-bridge 10 can be used alone or, as shown dotted in FIG. 1, with another half-bridge to drive an inductive load Z. The other half-bridge, whose switching elements are only shown schematically in FIG. 1, can be implemented using the same components as the half-bridge 10, but can also be implemented using other components. The load Z is driven by a current I flowing via the output 5 of the half-bridge circuit 10. A current I flowing in the direction shown in FIG. 1 can be achieved by the high-side switch 1 of this half-bridge circuit 10 being driven in the ON state in chopped mode, and, for example, by the low-side switch of the other half-bridge circuit being driven in the ON state continuously. The duty cycle or mark-space ratio of an ON-state drive of the high-side switch 1 here defines the mean value of the current I flowing into the load Z. If this load Z is a DC electric motor, then this current, and hence the duty cycle of the drive of the high-side switch 1, sets the speed of the motor.

A chopped drive of the high-side switch 1 of the half-bridge 10 is represented in FIG. 2 by a time waveform of a first drive signal S1 applied to the drive terminal of the high-side switch 1. It should be assumed for explanatory purposes that the high-side switch 1 is driven in the ON state during those time intervals when the first drive signal S1 assumes a high signal level (high level), and that the high-side switch 1 is driven in the OFF state during those time intervals when the first drive signal S1 assumes a low signal level (low level). The signal time waveform shown in FIG. 2 shows the first drive signal S1 only schematically. A high level of the first drive signal S1 shown in FIG. 2 represents here an electrical voltage between the gate terminal G and the emitter terminal E of the IGBT used as the high-side switch that is higher than a threshold voltage of this semiconductor switching element. Typical values for such a drive voltage for driving in the ON state lie in the range of about 10 to 20 V.

In a pulse-width modulated drive of the high-side switch, a current continues to flow in the direction I shown in FIG. 1 during those time intervals when the high-side switch 1 is in the OFF state. This current is made possible by the freewheeling element 4 of the low-side switch 2. In order to avoid unnecessary drive losses, it is provided here that, during those time intervals when the freewheeling element 4 is forward biased, the low-side switch 2 is not additionally driven in the ON state. In addition to the time waveform of the first drive signal S1, FIG. 2 also shows the time waveform of a second drive signal S2, which is applied to the drive terminal of the low-side switch 2. During the entire time interval when the high-side switch 1 is driven in chopped mode i.e. by a pulse-width modulated drive, this drive signal S2 has a low signal level or OFF level, with which the low-side switch 2 is driven in the OFF state. A freewheeling current is hence taken solely by the freewheeling element 4, in other words at any one point in time just one of the two semiconductor switching elements 1, 2 is being driven by a pulse-width modulated drive.

The low-side switch 2 of the half-bridge 10 is used to generate a current through the load Z that flows in the opposite direction to the current direction shown in FIG. 1. The high-side switch of the other half-bridge is here driven in the ON state while the low-side switch 2 of the half-bridge 10 is being driven in chopped mode. The duty cycle of the chopped drive of the low-side switch 2 here sets the mean value of the current flowing through the load Z. During the time intervals when the low-side switch 2 is in the OFF state for such a pulse-width modulated or chopped drive, the first freewheeling element 3 takes the load current I that continues to flow during these OFF intervals. The high-side switch 1 is driven continuously in the OFF state, i.e. the drive signal S1 has an OFF level, during the time interval of this chopped drive of the low-side switch 2. FIG. 2 also shows the time waveforms of the first and second drive signals S1, S2 for this case, where the references in brackets refer to this last described case of a chopped drive of the low-side switch 2.

FIG. 3 shows an example of a 3-phase power converter, which comprises three half-bridges 10₁, 10₂, 10₃, which are connected in parallel with each other, and which are each connected between terminals for the positive and negative supply potential V+, V−. Each of the half-bridges 10₁, 10₂, 10₃ has the same design as the half-bridge 10 explained above with reference to FIG. 1. All the details given in relation to FIG. 1 on implementing the half-bridge 10 apply accordingly to the implementation of the three half-bridges 10₁, 10₂, 10₃ shown in FIG. 3. It should also be mentioned in this context that the three half-bridges 10₁, 10₂, 10₃ that form a 3-phase power converter can have a different implementation. The implementation of the half-bridges 10₁, 10₂, 10₃ using in each case two series-connected n-channel IGBTs, as shown in FIG. 3, is to be considered merely as an example. In FIG. 3, components of the individual half-bridges identical to those in FIG. 1 are denoted by the same references, with the subscript “1” denoting the parts and signals of the first half-bridge 101, the subscript “2” denoting the parts and signals of the second half-bridge 102, and the subscript “3” denoting the parts and signals of the third half-bridge 103.

The 3-phase power converter shown in FIG. 3 is used to drive a 3-phase motor Z (shown dashed in FIG. 3), for example. Each of the terminals of such a three-phase load Z is connected to the respective output 5₁, 5₂, 5₃ of one of the half-bridges 10₁, 10₂, 10₃.

In order to drive such a three-phase inductive load Z, the 3-phase power converter generates a rotating field or in other words three output currents I1, I2, I3 that ideally have a mutual phase offset of 120°. In the example shown, I1 denotes the output current at the output 5₁ of the first half-bridge 10₁, I2 denotes the output current at the output 5₂ of the second half-bridge 10₂ and I3 denotes the output current at the output 5₃ of the third half-bridge 103.

Drive signals for the semiconductor switching elements of the three half-bridges can be generated so that a reference signal is provided for each of the half-bridges whose time waveform matches the required time waveform of the output current of the respective half-bridge, and so that drive signals for the two semiconductor switching elements of a half-bridge are generated using a comparison between this reference signal and another reference signal having a higher frequency than this reference signal, with the drive signals of the two semiconductor switching elements each being generated so that the two semiconductor switching elements are driven with respect to each other in a complementary fashion. Such a method, however, in which the two semiconductor switching elements of a half-bridge are each driven with respect to each other in a complementary fashion, results in relatively high drive losses. These drive losses are those losses associated with driving a semiconductor switching element in the ON state and OFF state. When IGBTs or MOSFETs are used as the semiconductor switching elements, these drive losses arise mainly from charging and discharging currents of the gate electrodes of these components.

In order to reduce the drive losses, in one example of a method for driving the semiconductor switching elements 1₁, 2₁, 1₂, 2₂, 1₃, 2₃ of the individual half-bridges 10₁, 10₂, 10₃, it is provided to prevent driving in the ON state that semiconductor switching element of the two semiconductor switching elements of a half-bridge during those time intervals when the freewheeling element associated with the semiconductor switching element is forward biased.

FIG. 4 uses signal time waveforms to illustrate an example of a method for driving the semiconductor switching elements of a 3-phase power converter such as shown in FIG. 3. The drive signals for the individual semiconductor switching elements are here generated using a comparison between first reference signals REF1, REF2, REF3 and a second reference signal FR. In the example shown, the first reference signals REF1, REF2, REF3 are sinusoidal signals each having a mutual phase offset of 120° and which are each used to generate the drive signals of a respective half-bridge 10₁, 10₂, 10₃. Trapezoidal signals could also be used instead of sinusoidal signals. In the example, the second reference signal FR is a triangular signal having a frequency that is higher than the frequency of the first reference signals.

The frequency of the first reference signals, i.e. the required frequency of the output currents, lies between 50 Hz and 500 Hz, for example, depending on the application. The frequency of the second reference signal equals between 5 kHz and 20 kHz, for example. In general, the frequency ratio between the frequency of the second reference signal and the frequencies of the first reference signal lies between 10:1 and 400:1. In the example shown, the second reference signal FR is a triangular signal, although a trapezoidal or saw-tooth signal could also be used correspondingly. Each of the three first reference signals REF1, REF2, REF3 is used together with the second reference signal FR to generate the respective drive signals for one of the three half-bridges. In the example shown, the drive signals S1₁, S2₂ for the semiconductor switching elements 1₁, 2₁ of the first half-bridge 10₁ are obtained by comparing the first reference signal REF1 with the second reference signal FR, the drive signals S₁, S2₂ for the semiconductor switching elements 1₂, 2₂ of the second half-bridge 102 are obtained by comparing the second reference signal REF2 of the first reference signals with the second reference signal FR, and the drive signals S1₃, S2₃ for the semiconductor switching elements 1₃, 2₃ of the third half-bridge 10₃ are obtained by comparing the third reference signal REF3 of the first reference signals with the second reference signal FR. In the description below, REF denotes generally one of the first reference signals, S1 denotes generally one of the drive signals of the high-side switches 1₁, 1₂, 1₃ of the half-bridge circuits 10₁, 10₂, 10₃, and S2 denotes generally one of the drive signals of the low-side switches 2₁, 2₂, 2₃ of the half-bridge circuits 10₁, 10₂, 10₃.

In the example shown, an ON level of the drive signal S1 of the high-side switch of a half-bridge circuit is generated whenever the first reference signal REF of this half-bridge circuit is greater than the second reference signal FR, and an ON level of the drive signal of the low-side switch of a half-bridge circuit is generated whenever the first reference signal REF of the respective half-bridge is smaller than the second reference signal FR.

During those time intervals when the freewheeling element of one of the semiconductor switching elements of a half-bridge 10₁, 10₂, 10₃ is forward biased, which is precisely when the other semiconductor switching element of this half-bridge is in the OFF state, it is also provided in the method shown in FIG. 4 to prevent this one semiconductor switching element from being driven in the ON state. The first half-bridge 10₁ of the 3-phase power converter shall be considered in order to explain this aspect. During a positive half-wave of the first reference signal REF1, the current I1 at the output 5₁ of this half-bridge flows in the direction shown in FIG. 3. To generate this current, the high-side switch 1₁ of this half-bridge 10₁ is driven by a pulse-width modulated drive during the positive half-wave.

A pulse-width modulated drive of any of the semiconductor switching elements comprises a plurality of successive drive cycles, each having an ON time interval during which the driven semiconductor switching element is in the ON state, and an OFF time interval during which the driven semiconductor switching element is in the OFF state. In the context of the present description, a pulse-width modulated drive is taken to mean only such a drive for which a plurality of drive cycles succeed each other whose period lies in the region of one period length of the second reference signal, or is shorter than half a period length of the first reference signal.

During the OFF time interval of the pulse-width modulated drive of the high-side switch 1₁ of the first half-bridge 10₁, the freewheeling element 4₁ of the low-side switch 2₁ is forward biased. The time interval during which the freewheeling element 4₁ of the low-side switch 2₁ is forward biased on every occasion that the high-side switch 1₁ is driven in the OFF state hence equals the time interval of a positive half-wave of the first reference signal REF1 in the example shown. In this method it is hence provided to prevent the low-side switch 2₁ being driven in the ON state during the positive half-wave of the first reference signal REF1. In a corresponding manner, the freewheeling element 3₁ of the high-side switch 1₁ is forward biased during a negative half-wave of the first reference signal when the low-side switch 2₁ is in the OFF state. Hence in the method shown in FIG. 4, the high-side switch 1₁ is prevented from being driven in the ON state during the time interval of a negative half-wave of the first reference signal REF1.

It is generally true for the method shown in FIG. 4 that during a positive half-wave of the first reference signal REF1, REF2, REF3 of one of the half-bridge circuits 10₁, 10₂, 10₃, the low-side switch 2₁, 2₂, 2₃ of the respective half-bridge 10₁, 10₂, 10₃ is prevented from being driven in the ON state, and that for a negative half-wave of the first reference signal REF1, REF2, REF3 of a half-bridge circuit 10₁, 10₂, 10₃, the high-side switch 1₁, 1₂, 1₃ of the respective half-bridge circuit 10₁, 10₂, 10₃ is prevented from being driven in the ON state.

FIG. 5 shows an example of a drive circuit for generating the drive signals of each of the semiconductor switching elements for a method described with reference to FIG. 4. This drive circuit has three drive units 6₁, 6₂, 6₃, which have the same design and which each generate the drive signals for the semiconductor switching elements of a half-bridge, i.e. a first drive unit 6₁ generates the drive signals S1₁, S2₁ for the first half-bridge circuit 10₁, a second drive unit 6₂ generates the drive signals S1₂, S2₂ for the second half-bridge circuit 10₂, and a third drive unit 6₃ generates the drive signals S1₃, S2₃ for the third half-bridge circuit 10₃. Identical components in these drive units 6₁, 6₂, 6₃ are each denoted by the same references, which only differ by the subscripts “1” for the first drive unit 6₁, “2” for the second drive unit 6₂ and “3” for the third drive unit 6₃.

The drive circuit also comprises a reference signal generator 7 for providing the second reference signal FR and, optionally, an offset unit 8, which adds a defined offset to the second reference signal FR. A signal provided at the output of this offset unit 8 is denoted by FR′ in FIG. 5. Each of the drive units 6₁, 6₂, 6₃ work in the same way. The first drive unit 6₁ is used below to explain how they work, and applies correspondingly to the two other drive units 6₂, 6₃.

The first drive unit 6₁ comprises a first reference signal generator 61₁, which provides the first reference signal REF1. This first reference signal REF1 is compared with the second reference signal FR by means of a first comparator 62₁. The first drive signal S1₁ is provided at the output of an AND Gate 64₁, to which are input the output signal from the first comparator 62₁ and the output signal from a second comparator 63₁. The second comparator 63₁ compares the first reference signal REF1 with a defined threshold value, which is zero in the example shown in FIG. 4. A chopped drive signal is provided at the output of the first comparator 62₁, which depends directly on the comparison of the first reference signal REF1 with the second reference signal FR. In the example shown, this chopped drive signal has an ON level during those time intervals when the first reference signal REF1 is greater than the second reference signal FR, and has an OFF level during those time intervals when the first reference signal REF1 is smaller than the second reference signal FR. This pulse-width modulated drive signal provided at the output of the first comparator 62₁, however, is only output by the AND gate 64₁ as the pulse width modulated first drive signal S1₁ during those time intervals when the first reference signal REF1 has its positive half-wave, i.e. is greater than zero.

To generate the second drive signal S2₁, the drive unit 6₁ comprises a second comparator 65₁, which compares the first reference signal REF1 with the second reference signal FR or, optionally, with the offset-added second reference signal FR′. The second drive signal S2₁ is provided at the output of a second AND gate 68₁, to which are input the output signal from the comparator 65₁ and the output signal from the second comparator 63₁, which has been inverted by an inverter 67₁. At the output of the third comparator 65₁ is provided continuously a chopped drive signal, which depends on a comparison of the first reference signal REF1 with the second reference signal FR, or with the offset-added second reference signal FR′, and which, in the example shown, assumes an ON level when the first reference signal REF1 is smaller than the second reference signal FR or the offset-added second reference signal FR′. The AND gate 68₁, however, blanks out this chopped drive signal, controlled by the inverted output signal from the second comparator 63₁ during those timing intervals when the first reference signal REF1 lies below the defined threshold value, i.e. in the example shown in FIG. 4 when it has a negative half-wave.

Comparing the first reference signal REF1 with the second reference signal FR for generating the first drive signal S1₁, and comparing the first reference signal REF1 with the offset-added second reference signal FR′ for generating the second drive signal S2′ guarantees that there is a dead time between an ON level of the first drive signal and a subsequent ON level of the second drive signal, so that cross currents of the half-bridge are avoided. In the example shown, the offset produced by the offset circuit is greater than zero.

To drive the load Z, at least the high-side switch of one of the half-bridges 10₁, 10₂, 10₃, and at least the low-side switch of another of the half-bridges must be in the ON state during one point in time. In the example shown in FIG. 4 of a method for controlling the half-bridges 10₁, 10₂, 10₃, the high-side switch and the low-side switch are driven by a pulse-width modulated drive, and to be precise during those time intervals when a drive is not prevented. FIG. 6 shows another method for driving the semiconductor switching elements. In this method it is provided to drive only the respective high-side switches of the half-bridge circuits by a pulse-width modulated drive, and to drive the low-side switches in the ON state continuously during those time intervals when driving the low-side switches in the ON state is not prevented. Referring to the first half-bridge 1, this means that the high-side switch is driven by a pulse-width modulated drive during the positive half-wave of the first reference signal REF1, during which time interval the low-side switch is prevented from being driven in an ON state, and that the low-side switch is driven continuously in the ON state during the negative half-wave of the first reference signal REF1, during which the high-side switch is prevented from being driven in an ON state. Correspondingly, the low-side switch of the second half-bridge 10₂ is driven continuously in the ON state during the negative half-wave of the second reference signal REF2, and the low-side switch of the third half-bridge 10₃ is driven continuously in the ON state during a negative half-wave of the third reference signal REF3.

FIG. 7 shows an example of a drive circuit for generating the drive signals shown in FIG. 6. This drive circuit differs from that shown in FIG. 5 in that the individual drive units 6₁, 6₂, 6₃ for generating the second drive signal S2₁, S2₂, S2₃ only comprise an inverter 66₁, 66₂, 66₃, which inverts the output signal of the second comparator 63₁, 63₂, 63₃.

Information about the time intervals during which the freewheeling element of a semiconductor switching element of a half-bridge is forward biased, when the other semiconductor switching element, driven by a pulse-width modulated drive, of the half-bridge is in the OFF state, is derived directly from the reference signals in the methods explained with reference to FIGS. 4 and 6. FIG. 8 shows another method for generating drive signals. It is provided in this method to derive information about these time intervals from the current direction of the current I flowing at the output 5 of the half-bridge 10. FIG. 8 shows only one half-bridge 10. The described method can obviously also be applied to all the half-bridges of a 3-phase power converter or an H-bridge.

In this method, a blanking circuit 8 is used, to which are supplied the drive signals S1′, S2′ for the high-side switch 1 and the low-side switch 2, and which is designed to modify or intermittently blank out these drive signals S1′, S2′ and hence to generate drive signals S1, S2, which are applied to the semiconductor switching elements. The drive signals S1′, S2′ supplied to the blanking circuit 8 can, for example, be drive signals that are generated directly by comparing a first reference signal with a second reference signal, i.e. those drive signals provided at the outputs of the first comparator 62 and the second comparator 65 as shown in the drive circuit in FIG. 5. The blanking circuit shown in FIG. 8 comprises a current-direction detector 81, 82, which is designed to detect a current direction of the current I flowing at the output 5. This current-direction detector 81, 82 generates a current-direction signal S82, which contains information about the current direction of the current I. This current-direction signal S82 is used to generate the first and second drive signals S1, S2 from the drive signals S1′, S2′ supplied to the blanking circuit 8. The first drive signal S1 is generated such that during those time intervals when the current I is flowing in the opposite direction to the current direction shown in FIG. 8, the first drive signal S1 is set to an OFF level, i.e. the high-side switch 1 is prevented from being driven in the ON state by the supplied drive signal S1′. In other words, the first drive signal S1 is obtained from the supplied drive signal S1′ by intermittent blanking out of the supplied drive signal S1′ during those time intervals when the current flows in the opposite direction to the current direction shown in FIG. 8. During these time intervals when the current flows in the opposite direction to the current direction shown in FIG. 8, the freewheeling element 3 of the high-side switch 1 is forward biased at those moments in time when, with a pulse-width modulated drive of the low-side switch 2, the low-side switch 2 is in the OFF state. The first drive signal S1 is generated from the supplied drive signal S1′ by an AND gate 83, to which are input the supplied signal S1′ and the current-direction signal S82.

In a manner corresponding to generation of the first drive signal S1, the second drive signal S2 is generated by blanking out the supplied drive signal S2′ during those time intervals when the current I is flowing in the current direction shown in FIG. 8. During these time intervals, the freewheeling element 4 of the low-side switch 2 is forward biased at those moments in time when, with a pulse-width modulated drive of the high-side switch 1, the high-side switch 1 is in the OFF state. To generate the second drive signal S2, the blanking circuit 8 shown has an AND gate 84, to which are input the second drive signal S2′ and the current-direction signal S82 in inverted form. The inverted current-direction signal S82 is provided at the output of an inverter 85, to which is input the current-direction signal S82.

In the example shown, the current-direction detector 81, 82 comprises a current-measurement arrangement 81, which generates a current-measurement signal S81, which is input to a comparator 82. This comparator 82 compares the current-measurement signal S81 with a defined threshold value, e.g. zero, and provides the current-direction signal S82 at its output. In the example shown, the current-direction signal S82 has a high level when the current is flowing in the direction shown in FIG. 8, and has a low level when the current is flowing in the opposite direction to the current direction shown in FIG. 8.

It should be mentioned that driver circuits (not shown) can be connected before the drive terminals of the semiconductor switching elements, these driver circuits being used for converting signal levels of the signals provided at the output of the blanking circuit into signal levels suitable for driving the semiconductor switching elements.

Instead of measuring the current directly, it is provided in another method to compute the current direction. The first and second reference signals, for example, are provided by a microcontroller (not shown), which uses these signals to drive the individual semiconductor switching elements. A mathematical model of the load switched by the half-bridge can be stored in this microcontroller, which enables the microcontroller to compute for each phase of each reference signal the direction of the currents at the outputs of each half-bridge, and hence to generate enable signals that enable or inhibit driving of each of the semiconductor switching elements.

Instead of determining the direction of the current I flowing at the output 5 of the half-bridge 10, in order to detect those time intervals during which the freewheeling element of a semiconductor switching element is forward biased at those moments in time when, with a pulse-width modulated drive, the other semiconductor switching element is in the OFF state, there is also the option, referring to FIG. 9, of evaluating the voltage across and/or the current through the freewheeling elements. In the example shown, these freewheeling elements 3, 4 are connected to evaluation circuits, which are designed to evaluate a voltage drop across these freewheeling elements 3, 4 or a current through the freewheeling elements 3, 4, and which each generate an enable signal S86, S87. These enable signals are input to AND gates 83, 84, whose operation has already been explained in connection with FIG. 8.

The evaluation circuits 86, 87 are designed to generate an enable level of the enable signals S86, S87 when the freewheeling elements are not forward biased, or rather to generate a non-enable level when the freewheeling elements are forward biased. The enable level is a high-level in the example. In this case, the drive signals S1′, S2′ can pass through the AND gates 83, 84 to drive the semiconductor switches 1, 2.

The drive methods described above, in particular the drive method described with reference to FIG. 6, are particularly suitable for a 3-phase power converter such as shown in FIG. 10. The three half-bridges 10₁, 10₂, 10₃ of this power converter each have a MOSFET as the high-side switch and an IGBT as the low-side switch. The MOSFETs are each n-channel MOSFETs in this example, and the IGBTs are n-channel IGBTs. Obviously, p-channel components could also be used in this context.

Separate freewheeling elements can be provided as the freewheeling elements of the MOSFETs, but it is also possible to use the integral MOSFET body diode as the freewheeling element.

The described method allows a significant reduction in the drive losses of the switching elements compared with conventional methods in which the switching elements are also driven in the ON state when the switching element is unable to conduct the load current, i.e. for an IGBT when a voltage lies in the reverse direction. Unlike MOSFETS, IGBTs are unable to conduct a current under such a reverse voltage even when they are driven in the ON state. The method, however, is also suitable in conjunction with components such as MOSFETS that are suitable for conducting a current in the reverse direction when driven in the ON state.

The method is also suitable in conjunction with RCIGBTs (Reverse Conducting IGBT). These are IGBTs that include an integral freewheeling function, but which have high ON-state losses when they are additionally driven in the ON state in the reverse conducting direction for which there is no need to drive the gate electrode.

It is true generally for the present method that semiconductor switching elements having a forward direction and a reverse direction are not driven in the ON state when they are reverse biased. For n-channel components, a reverse bias means applying a positive voltage between emitter and collector (for an IGBT) or between source and drain (for a MOSFET). For p-channel components, a reverse bias means applying a negative voltage between emitter and collector (for an IGBT) or between source and drain (for a MOSFET).

The methods described above by way of example, in which the first reference signals, an output current of the half-bridge or currents through, or voltages across, freewheeling elements are evaluated, can be used to determine whether such a reverse bias exists or whether the half-bridge circuit is in an operating state in which such a reverse bias of a semiconductor switching element can occur.

1. A method for driving a half-bridge circuit comprising two semiconductor switching elements, each having a load path and a drive terminal, and a freewheeling element coupled in parallel with the load path, the method comprising:
preventing at least one of the two semiconductor switching elements from being driven in an ON state at least during a time interval when its freewheeling element is forward biased.

2. The method according to claim 1, further comprising:
driving one of the two semiconductor switching elements in a chopped mode during drive intervals spaced in; and
preventing an other of the two semiconductor switching elements from being driven in the ON state during the drive intervals.

3. The method according to claim 1, further comprising:
generating a first drive signal for a first of the two semiconductor switching elements, wherein generating the first drive signal comprises comparing a first reference signal with a second reference signal;
generating a second drive signal for a second of the two semiconductor switching elements, wherein generating the second drive signal comprises comparing the first reference signal with the second reference signal;
preventing the second semiconductor switching element from being driven in the ON state when the first reference signal lies above a defined threshold value; and
preventing the first semiconductor switching element from being driven in the ON state when the first reference signal lies below a defined threshold value.

4. The method according to claim 3, wherein:
the first reference signal comprises a sinusoidal or trapezoidal signal;
the second reference signal comprises a triangular signal or a trapezoidal signal; and
a frequency of the second reference signal is greater than a frequency of the first reference signal.

5. The method according to claim 1, wherein the half-bridge circuit comprises an output, wherein the method further comprises:
determining a current direction of a current flowing at the output; and
preventing one of the two semiconductor switching elements from being driven in the ON state for a first current direction of the current;
and preventing an other of the two semiconductor switching elements from being driven in the ON state for a second current direction of the current that is opposite to the first current direction.

6. The method according to claim 1, further comprising:
determining a polarity of a voltage across the load path of at least one of the semiconductor switching elements; and
preventing the semiconductor switching element from being driven in the ON state when the voltage across the load path of the at least one of the semiconductor switching element has a defined polarity.

7. A method for driving a half-bridge circuit comprising two semiconductor switching elements, each having a load path and a drive terminal, the method comprising:
determining a current direction of a current flowing at an output; and
preventing one of the two semiconductor switching elements from being driven in an ON state for a first current direction of the current; and
preventing an other of the two semiconductor switching elements from being driven in the ON state for a second current direction of the current that is opposite to the first current direction.

8. A method for driving a half-bridge circuit comprising two semiconductor switching elements, each having a load path and a drive terminal, the method comprising:
determining a polarity of a voltage across the load path of at least one of the semiconductor switching elements; and
preventing the semiconductor switching element from being driven in an ON state when the voltage across the load path of the at least one of the semiconductor switching elements has a defined polarity.

9. A method for driving a half-bridge circuit comprising two semiconductor switching elements, each having a load path, a drive terminal a forward direction and a reverse direction, the method comprising:
preventing at least one of the two semiconductor switching elements from being driven in an ON state at least during a time interval when this semiconductor switching element is reverse biased.

10. A half-bridge circuit system comprising a controller having a plurality of outputs, wherein:
the plurality of controller outputs are configured to be coupled to a half-bridge circuit comprising a plurality of switching elements, wherein each of the plurality of switching elements comprises an associated parallel coupled freewheeling element;
the controller is configured to activate at least one of the plurality of switching elements; and
the controller is configured to prevent the activation of the at least one of the plurality switching elements if the associated parallel coupled freewheeling element is conducting current.

11. The half-bridge circuit system of claim 10, wherein the controller further comprises:
a first reference input comprising a signal at a first frequency;
a second reference input comprising a signal at a second frequency greater than the first frequency;
a first comparator comprising
a first input coupled to the first reference input,
a second input coupled to the second reference input, and
an output configured to be coupled to a first of the plurality of switching elements;
a second comparator comprising
a first input coupled to the second reference input,
a second input coupled to the first reference input, and
an output configured to be coupled to a second of the plurality of switching elements;
a selection circuit configured to
determine a polarity of the first reference input,
enable the output of the first comparator and disable the output of the second comparator if a first polarity is determined, and
enable the output of the second comparator and disable the output of the second comparator if a second polarity is determined.

12. The half-bridge circuit system of claim 11, wherein the outputs of the first and second comparators comprise chopped mode signals.

13. The half-bridge circuit system of claim 11, further comprising an offset voltage coupled between the second reference input and the first input of the second comparator.

14. The half-bridge circuit system of claim 11, further comprising a half-bridge circuit comprising:
a high-side switching element coupled in parallel with a high-side freewheeling element; and
a low-side switching element coupled in parallel with a low-side freewheeling element.

15. The half-bridge circuit system of claim 14, wherein:
the low-side and high-side switching elements comprise an insulated gate bipolar transistors (IGBTs); and
the low-side and high-side freewheeling elements comprises diodes.

16. The half-bridge circuit system of claim 10, wherein the controller further comprises a blanking circuit comprising:
a current direction detector configured to be coupled to an output of the half-bridge circuit; and
a selection circuit configured to disable a first of the plurality of switching elements if the current direction detector detects a current flowing in a first direction, and disable a second of the plurality of switching elements if the current direction detector detects a current flowing in a second direction.

17. The half-bridge circuit system of claim 10, wherein the controller further comprises:
an evaluation circuit configured to determine if an associated parallel coupled freewheeling element of one of the plurality of switching elements is forward biased;
a selection circuit configured to disable the one of the plurality of switching elements if the evaluation circuit determines that the associated parallel coupled freewheeling element is forward biased.

18. The half-bridge circuit system of claim 10, wherein the controller is further configured to drive a plurality of half-bridge switching circuits.

19. The half-bridge circuit system of claim 18, further comprising three half-bridge circuits, each half bridge circuit comprising:
a high-side switching element coupled in parallel with a high-side freewheeling element; and
a low-side switching element coupled in parallel with a low-side freewheeling element.

20. The half-bridge circuit system of claim 19, further comprising a 3-phase motor coupled to the three half-bridge circuits.
